(19) United States
(12) Patent Application Publication
(10) Pub. No.: US 2018/0182869 A1
(43) Pub. Date: Jun. 28, 2018

(54) THIN FILM TRANSISTOR AND METHOD OF FABRICATING THE SAME

(71) Applicant: Shenzhen China Star Optoelectronics Technology Co., Ltd., Shenzhen, Guangdong (CN)

(72) Inventor: Yang LIU, Shenzhen, Guangdong (CN)

(73) Assignee: Shenzhen China Star Optoelectronics Technology Co., Ltd., Shenzhen, Guangdong (CN)

(21) Appl. No.: 15/310,430

(22) PCT Filed: Sep. 9, 2016
(86) PCT No.: PCT/CN2016/098572

§ 371 Date: Nov. 10, 2016

(30) Foreign Application Priority Data
Jul. 20, 2016 (CN) 201610576516.X

(51) Int. Cl. H01L 29/66; H01L 29/786; H01L 21/02; H01L 21/44; H01L 29/49

(52) U.S. Cl. CPC H01L 29/66969; H01L 29/7869; H01L 29/78603; H01L 29/4908; H01L 21/02258; H01L 21/44; H01L 21/02244

(57) ABSTRACT

The present application provides a method of fabricating a thin film transistor, including forming an active layer on the substrate; simultaneously forming a source electrode and a drain electrode respectively in contact with both ends of the active layer on the substrate, and forming an insulating layer covering the active layer, the source electrode and the drain electrode; and simultaneously forming a gate electrode and a passivation layer covering the insulating layer. The present application also provides a thin film transistor formed by the fabricating method thereof. The thin film transistor is performed at ambient temperature in order to achieve the fabricating of thin-film transistors on a flexible substrate without thermostability, and even no need of the expensive equipment such as PECVD and etc., can greatly reduce the process cost of manufacturing the flexible display.

### FIELD OF THE INVENTION

The present application relates to a method for manufacturing an electrical device, in particular to a thin film transistor and a method for manufacturing the same.

### BACKGROUND OF THE INVENTION

The flexible display has the characteristics of lightness, thinness, able to bend and folding, comparing to the flat display of the traditional rigid substrate (such as glass substrate), has broad application prospects.

In the traditional flat display, especially in the manufacturing process of the thin film transistor, due to the production process temperature, especially the PECVD process temperature is higher, the requirement of the temperature of the substrate is higher. Then the flexible substrate generally use the organic polymer materials, it is difficult to withstand higher temperature, if the direct application of the traditional production process (such as PECVD process) will hinder the development of flexible display technology.

### SUMMARY OF THE INVENTION

In order to solve the technology problem above, the present application provides a thin film transistor adapting the anodic oxidation treatment process and the method of fabricating the same.

According to one aspect of the present application is provided a method of fabricating a thin film transistor, including: forming an active layer on the substrate; simultaneously forming a source electrode and a drain electrode respectively in contact with both ends of the active layer on the substrate, and forming an insulating layer covering the active layer, the source electrode and the drain electrode; and simultaneously forming a gate electrode and a passivation layer covering the insulating layer.

Further the active layer is formed by a metal oxide semiconductor material on the substrate. Further the specific method of “simultaneously forming a source electrode and a drain electrode respectively in contact with both ends of the active layer on the substrate, and forming an insulating layer covering the active layer, the source electrode and the drain electrode” including: forming a metal layer on the substrate and covered the active layer; forming a photoresist layer on the metal layer corresponding to the regions of the source electrode and the drain electrode to be formed; performing an anodic oxidation treatment to the metal layer, wherein the metal layer not covered by the photoresist layer is oxidized, the metal layer covered by the photoresist layer is not oxidized; and ashing the photoresist layer, continuously performing the anodic oxidation treatment to the unoxidized metal layer, oxidizing the not oxidized surface of the metal layer, so that to form the insulating layer with the oxidized metal layer not covered by the photoresist layer, after the continuously performed anodic oxidation treatment, the unoxidized metal layer forms the source electrode and the drain electrode.

Further the specific method of “simultaneously forming a gate electrode and a passivation layer covering the insulating layer” including: forming a metal layer on the insulating layer; forming a photoresist layer on the metal layer corresponding to the region of the gate electrode to be formed; removing the metal layer not covered by the photoresist layer; and ahsing the photoresist layer, performing an anodic oxidation treatment to the rest metal layer, the rest surface of the metal layer is oxidized to form the passivation, the unoxidized metal layer forms the gate electrode.

According to one aspect of the present application is provided a thin film transistor, including: an active layer on a substrate; a source electrode and a drain electrode on the substrate and in contact with both ends of the active layer; an insulating layer on the substrate and covering the active layer, the source electrode and the drain electrode; a gate electrode on the insulating layer; and a passivation layer on the insulating layer and covering the gate electrode.

Further the active layer is made of a metal oxide semiconductor material.

Further the substrate is a flexible substrate or a rigid substrate.

Further the active layer, the source electrode and the drain electrode are simultaneously formed by an anodic oxidation treatment.

Further the gate electrode and the passivation layer are simultaneously formed by an anodic oxidation treatment.

The advantage of the present application is: the present application is combined the method of fabricating the metal oxide semiconductor thin film transistor (TFT) with the anodic oxidation technology, the entire fabricating process is performed at ambient temperature in order to achieve the fabricating of thin-film transistors on a flexible substrate without thermostability, and even no need of the expensive equipment such as PECVD and etc., can greatly reduce the process cost of manufacturing the flexible display.

### BRIEF DESCRIPTION OF THE DRAWINGS

In order to more clearly illustrate the embodiments of the present application or prior art, the following figures will be described in the embodiments are briefly introduced. It is obvious that the drawings are merely some embodiments of the present application, those of ordinary skill in this field can obtain other figures according to these figures without paying the premise.

FIG. 1 shows a schematic structure of a thin film transistor according to an embodiment of the present application; and

FIGS. 2A to 2H show a flow chart of a method of manufacturing a thin transistor according to an embodiment of the present application.

### DETAILED DESCRIPTION OF PREFERRED EMBODIMENTS

Embodiments of the present application are described in detail with the technical matters, structural features, achieved objects, and effects with reference to the accompanying drawings as follows. It is clear that the described embodiments are part of embodiments of the present application, but not all embodiments. Based on the embodiments of the present application, all other embodiments to those of ordinary skill in the premise of no creative efforts obtained should be considered within the scope of protection of the present application.

Specifically, the terminologies in the embodiments of the present application are merely for describing the purpose of the certain embodiment, but not to limit the invention. Examples and the claims be implemented in the present application requires the use of the singular form of the book “an”, “the” and “the” are intend to include most forms unless the context clearly dictates otherwise. It should also be understood that the terminology used herein that “and/or” means and includes any or all possible combinations of one or more of the associated listed items.

In the drawings, in order to clarity of the device, the thicknesses of the layers and regions are exaggerated and the same reference numerals refer to the same elements throughout the drawings.

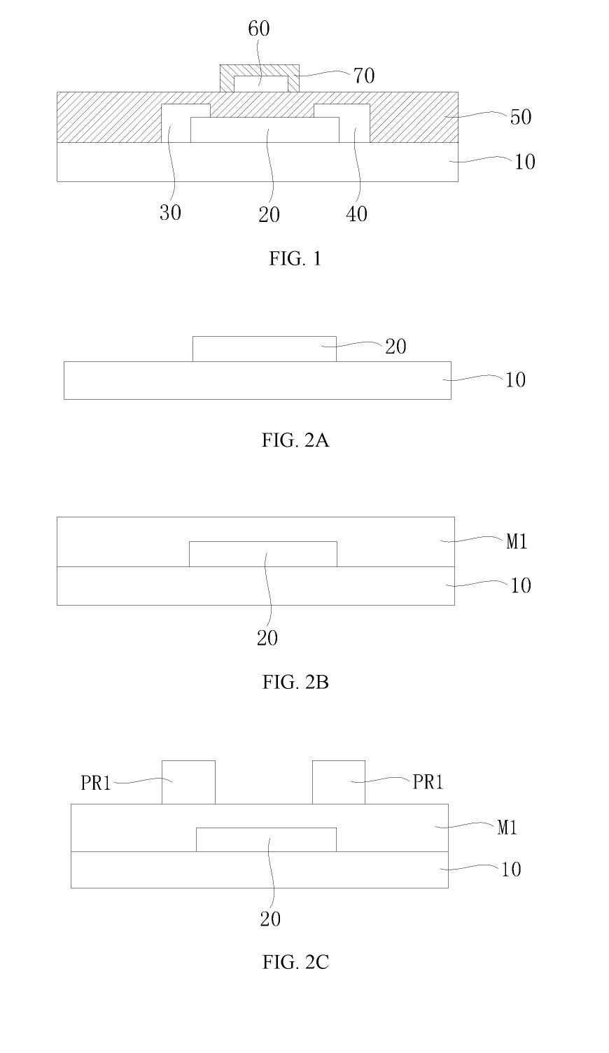

FIG. 1 shows a schematic structure of a thin film transistor according to an embodiment of the present application.

Referring to FIG. 1, a thin film transistor according to an embodiment of the present application has a top gate structure, includes an active layer 20 on a substrate 10; a source electrode 30 and a drain electrode 40 on the substrate 10 and in contact with both ends of the active layer 20, respectively; an insulating layer 50 on the substrate 10 and covering the active layer 20, the source electrode 30 and the drain electrode 40; a gate electrode 60 on the insulating layer 50; a passivation layer 70 on the insulating layer 50 and covering the gate electrode 60.

Preferably, the substrate 10 can be a flexible substrate made of a flexible material, but the present application is not limited thereto. For example, the substrate 10 can be a glass substrate or other rigid substrate.

Alternatively, the active layer 20 is made of a metal oxide semiconductor material, such as Zinc Oxide (ZnO), Indium Oxide (as In₂O₃), Tin Oxide (of SnO₂) and the like.

Alternatively, the source electrode 30, the drain electrode 40 and the gate electrode 60 can be made of a metallic material or an alloy material such as Aluminum, Magnesium, Titanium and other metals and alloys.

Alternatively, the anodic oxidation process can be used simultaneously to form the source electrode 30, the drain electrode 40 and the insulating layer 50. Wherein the insulating layer 50 can be a metal oxide of the material or alloy material forming the source electrode 30, the drain electrode 40.

Alternatively, the anodic oxidation process can be used simultaneously form the passivation layer 70 and the gate electrode 60. Wherein, the passivation layer 70 can be a metal oxide of the material or alloy material forming the gate electrode 60.

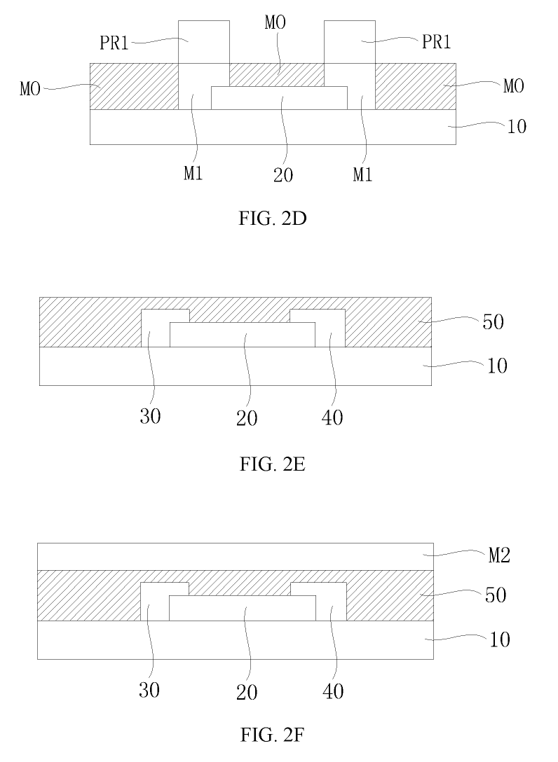

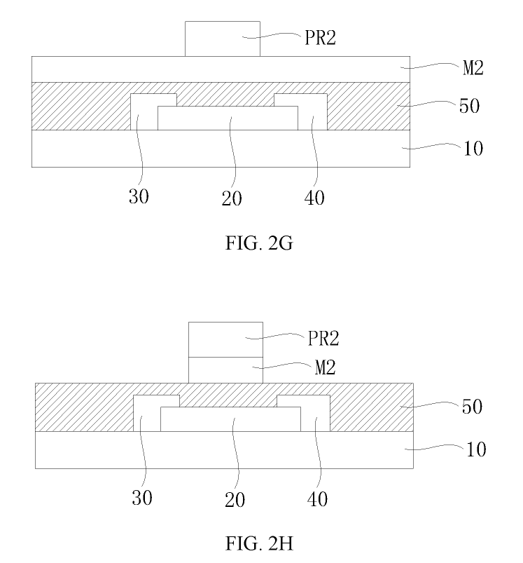

FIGS. 2A to 2H show a flow chart of a method of manufacturing a thin film transistor according to an embodiment of the present application.

Referring to 2A, the active layer 20 is formed on the substrate 10. Specifically, first, a metal oxide semiconductor material layer is deposited on the substrate 10. Next, the metal oxide semiconductor material layer is exposed, etched to form the active layer 20.

Referring to 2B, a metal layer M1 is formed on the substrate 10 and covering the active layer 20. Specifically, the metal layer M1 is deposited on the substrate 10 and covering the active layer 20 by a suitable deposition method.

Referring to FIG. 2C, a photoresist layer PR1 is formed on the metal layer M1 corresponding to the regions of the source electrode and the drain electrode to be formed (such as the region of both ends of the active layer 20). Here, two photoresist layer PR is formed on the metal layer M1, which one is corresponding to the region of the source electrode to be formed, and the other is corresponding to the region of the drain electrode to be formed.

Referring to FIG. 2D, performing an anodic oxidation treatment to the metal layer M1, wherein the metal layer not covered by the photoresist layer is oxidized to form a metal oxide layer MO, the metal layer covered by the photoresist layer M1 is not oxidized.

Referring to FIG. 2E, ashing the photoresist layer PR1, an anodic oxidation treatment is continuously performing to the unoxidized metal layer M1, to oxidize the not oxidized surface of the metal layer M1, so that to form the insulating layer 50 with the oxidized metal layer (MO illustrated in FIG. 2D) not covered with the photoresist layer, after the continuously performed anodic oxidation treatment, the unoxidized metal layer forms the source electrode 30 and the drain electrode 40.

Referring to FIG. 2F, forming a metal layer M2 on the insulating layer 50. Specifically, the metal layer M2 is deposited on the insulating layer 50 by a suitable deposition method.

Referring to FIG. 2G, a photoresist layer PR2 is formed on the metal layer M2 corresponding to the region of the gate electrode to be formed.

Referring to FIG. 2H, after the processes of exposure and etching, the metal layer M2 not covered by the photoresist layer PR2 is removed.

Back to referring to FIG. 1, ahsing the photoresist layer PR2, an anodic oxidation treatment is performed to the unoxidized metal layer M2, the rest surface of the metal layer M2 is oxidized to form the passivation 70, the unoxidized metal layer forms the gate electrode 60.

In summary, according to the thin film transistor and method of fabricating the same of the embodiment of the present application, the method of fabricating the metal oxide semiconductor (TOS) thin film transistor (TFT) is combined with the anodic oxidation technology, the entire fabricating process is performed at ambient temperature in order to achieve the fabricating of thin-film transistors on a flexible substrate without thermostability, and even no need of the expensive equipment such as PECVD and etc., can greatly reduce the process cost of manufacturing the flexible display.

Above are embodiments of the present application, which does not limit the scope of the present application. Any modifications, equivalent replacements or improvements within the spirit and principles of the embodiment described above should be covered by the protected scope of the invention.

What is claimed is:

1. A method of fabricating a thin film transistor, comprising:
forming an active layer on the substrate;
forming a source electrode and a drain electrode respectively in contact with both ends of the active layer on the substrate, simultaneously, and forming an insulating layer covering the active layer, the source electrode and the drain electrode; and
forming a gate electrode and a passivation layer covering the insulating layer, simultaneously.

2. The method of fabricating a thin film transistor according to claim 1, wherein the active layer is formed by a metal oxide semiconductor material on the substrate.

3. The method of fabricating a thin film transistor according to claim 1, wherein the specific method of “simultaneously forming a source electrode and a drain electrode respectively in contact with both ends of the active layer on the substrate, and forming an insulating layer covering the active layer, the source electrode and the drain electrode” comprising:
forming a metal layer on the substrate and covered the active layer;
forming a photoresist layer on the metal layer corresponding to the regions of the source electrode and the drain electrode to be formed;
performing an anodic oxidation treatment to the metal layer, wherein the metal layer not covered by the photoresist layer is oxidized, the metal layer covered by the photoresist layer is not oxidized; and
ashing the photoresist layer, continuously performing the anodic oxidation treatment to the unoxidized metal layer, oxidizing the not oxidized surface of the metal layer, so that to form the insulating layer with the oxidized metal layer not covered by the photoresist layer, after the continuously performed anodic oxidation treatment, the unoxidized metal layer forms the source electrode and the drain electrode.

4. The method of fabricating a thin film transistor according to claim 1, wherein the specific method of “forming a gate electrode and a passivation layer covering the insulating layer, simultaneously” comprising:
forming a metal layer on the insulating layer;
forming a photoresist layer on the metal layer corresponding to the region of the gate electrode to be formed;
removing the metal layer not covered by the photoresist layer; and
ahsing the photoresist layer, performing an anodic oxidation treatment to the rest metal layer, the rest surface of the metal layer is oxidized to form the passivation, the unoxidized metal layer forms the gate electrode.

5. The method of fabricating a thin film transistor according to claim 3, wherein the specific method of “forming a gate electrode and a passivation layer covering the insulating layer, simultaneously” comprising:
forming a metal layer on the insulating layer;
forming a photoresist layer on the metal layer corresponding to the region of the gate electrode to be formed;
removing the metal layer not covered by the photoresist layer; and
ahsing the photoresist layer, performing an anodic oxidation treatment to the rest metal layer, the rest surface of the metal layer is oxidized to form the passivation, the unoxidized metal layer forms the gate electrode.

6. The method of fabricating a thin film transistor according to claim 1, wherein the substrate is a flexible substrate or a rigid substrate.

7. A thin film transistor, comprising:
an active layer on a substrate;
a source electrode and a drain electrode on the substrate and in contact with both ends of the active layer;
an insulating layer on the substrate and covering the active layer, the source electrode and the drain electrode;
a gate electrode on the insulating layer; and
a passivation layer on the insulating layer and covering the gate electrode.

8. The thin film transistor according to claim 7, wherein the active layer is made of a metal oxide semiconductor material.

9. The thin film transistor according to claim 7, wherein the substrate is a flexible substrate or a rigid substrate.

10. The thin film transistor according to claim 7, wherein the active layer, the source electrode and the drain electrode are simultaneously formed by an anodic oxidation treatment.

11. The thin film transistor according to claim 7, wherein the gate electrode and the passivation layer are simultaneously formed by an anodic oxidation treatment.

12. The thin film transistor according to claim 10, wherein the gate electrode and the passivation layer are simultaneously formed by an anodic oxidation treatment.
